(19) United States
(12) Patent Application Publication
(10) Pub. No.: US 2012/0155143 A1
(43) Pub. Date: Jun. 21, 2012

(54) SEMICONDUCTOR DEVICE

(75) Inventor: Sun Mi CHOI, Gwangmyeong-si (KR)

(73) Assignee: HYNIX SEMICONDUCTOR INC., Icheon-si (KR)

(21) Appl. No.: 13/331,069

(22) Filed: Dec. 20, 2011

(30) Foreign Application Priority Data
Dec. 20, 2010 (KR) 10-2010-0130523

(51) Int. Cl. G11C 5/06; H01L 27/088

(52) U.S. Cl. 365/72; 257/368; 257/E27.06

(57) ABSTRACT

A semiconductor device includes a plurality of gates of high voltage transistors configured to couple a plurality of global word lines to a plurality of local word lines and the plurality of local word lines arranged over each of the gates. The plurality of local word lines is arranged within a width of the gate.

### CROSS-REFERENCE TO RELATED APPLICATION

Priority is claimed to Korean patent application number 10-2010-0130523 filed on Dec. 20, 2010, the entire disclosure of which is incorporated herein by reference in its entirety.

### BACKGROUND

Exemplary embodiments relate generally to a semiconductor device and, more particularly, to a semiconductor device having an electrical characteristic controlled by adjusting the arrangement of metal wires over a high voltage transistor.

Some semiconductor devices such as flash memory device includes pass transistors for supplying operating voltages to word lines coupled to memory cells. The pass transistors function to electrically connect global word lines to the word lines of a selected memory block, but block the connection between the global word lines and the word lines of unselected memory blocks in order to prevent the operating voltage from being supplied to the word lines of the unselected memory blocks. The pass transistor is formed of a high voltage transistor in order to transfer a high operating voltage, such as a program voltage, to the word lines.

FIG. 1 is a cross-sectional view of a known semiconductor device for illustrating a pass transistor for coupling global word lines to local word lines and the local word lines arranged over a gate.

Referring to FIG. 1, a transistor gate 14 comprising a gate insulation layer 11, a gate conductive layer 12, and a metal layer 13 is formed on a semiconductor substrate 10. Junctions 15 and 16 are formed by performing an ion implantation process on the active regions of the semiconductor substrate neighboring the transistor gate 14. Although not shown, the junctions 15 and 16 may be coupled to the global word lines and the local word lines, respectively.

A plurality of metal wires M1 to M9 is formed on the interlayer dielectric layer 17 formed on the entire structure including the transistor gate 14. Here, the metal wires M1 to M9 are the local word lines coupled to the memory cells of a memory block.

In the known art, some (for example, M1 and M9) of the metal wires M1 to M9 are formed in the source and drain regions 15 and 16 among the plurality of metal wires M1 to M9 arranged over the transistor gate 14. Therefore, when a high operating voltage is supplied to the global word lines, the high operating voltage may be supplied to the junction coupled to the global word lines. Thus, the voltage of a metal wire (for example, M9) arranged over the junction rises owing to a coupling effect. Accordingly, sheet resistance of the junction may increase and thus the voltages of the global word lines may drop.

### BRIEF SUMMARY

Exemplary embodiments relate to the metal wires of a semiconductor device, which are capable of preventing an increase in the sheet resistance of a junction and a drop in the voltages of global word lines by reducing the interval and width of metal wires and arranging the metal wires over the gate of a high voltage transistor.

A semiconductor device according to an aspect of the present disclosure includes a memory block configured to include a plurality of memory cells having gates coupled to a plurality of local word lines, a voltage generator configured to supply operating voltages to a plurality of global word lines, and a pass selector configured to include a plurality of high voltage transistors for coupling the plurality of local word lines to the plurality of global word lines. Here, the plurality of local word lines is disposed over each of the high voltage transistors and disposed within a width of a gate for the high voltage transistor.

A semiconductor device according to another aspect of the present disclosure includes a memory block configured to include a plurality of memory cells having gates coupled to a plurality of local word lines, a voltage generator configured to supply operating voltages to a plurality of global word lines, and a pass selector configured to include a plurality of high voltage transistors for coupling the plurality of local word lines to the plurality of global word lines. Here, the plurality of local word lines is disposed over each of the gates and disposed within a width of the gate.

A semiconductor device according to yet another aspect of the present disclosure includes high voltage transistors formed on a semiconductor substrate, source and drain regions formed within the semiconductor substrate on both sides of each of the high voltage transistors, and wires disposed only over a gate for the high voltage transistor not to overlap with the source and drain regions.

### BRIEF DESCRIPTION OF THE DRAWINGS

FIG. 1 is a cross-sectional view of a known semiconductor device for illustrating the metal wires of the semiconductor device;

FIG. 2 is a circuit diagram of a semiconductor device according to an embodiment of the present invention;

FIG. 3 is a cross-sectional view of the semiconductor device for illustrating a high voltage transistor and metal wires arranged over the high voltage transistor shown in FIG. 2;

FIG. 4 is a plan view of the high voltage transistor and the metal wires shown in FIG. 3; and

FIG. 5 is a cross-sectional view of a semiconductor device for illustrating a high voltage transistor and metal wires arranged over the high voltage transistor according to an embodiment of the present invention.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

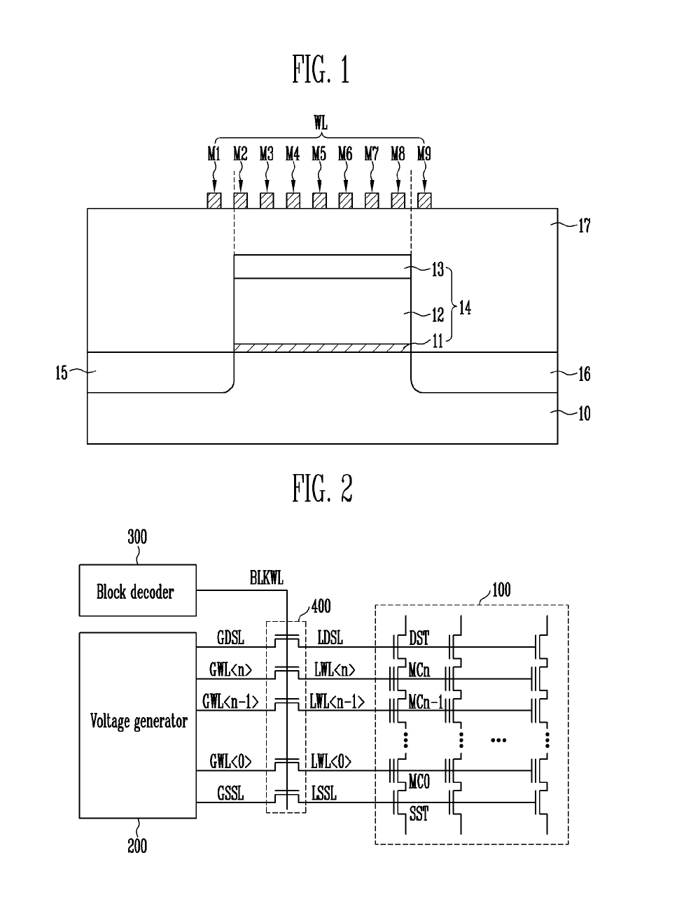

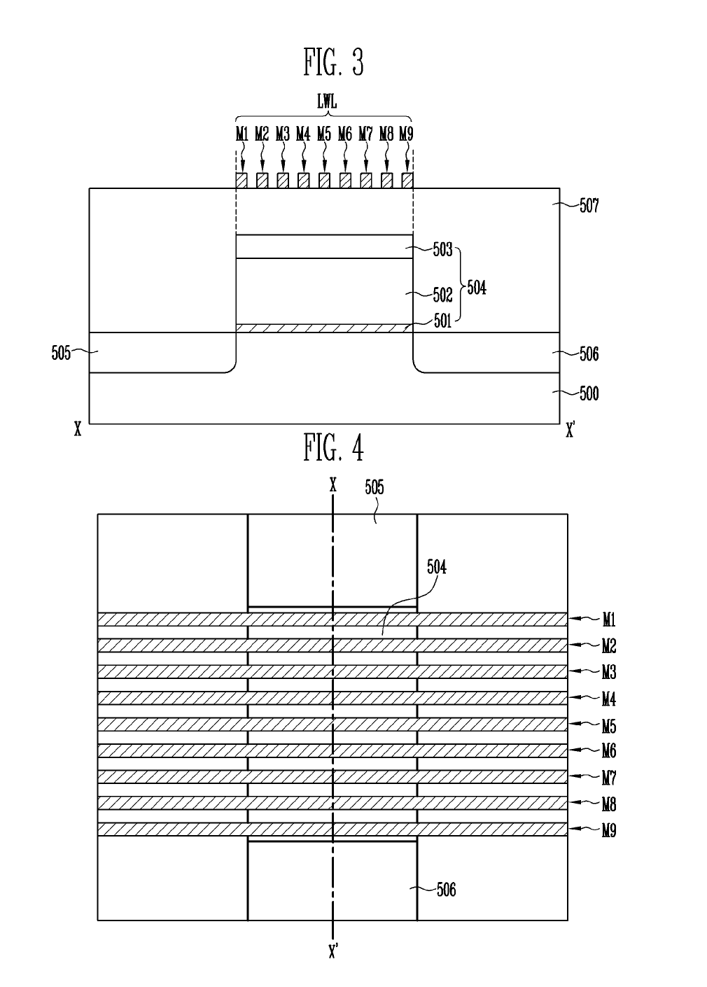

FIG. 2 is a circuit diagram of a semiconductor device according to an embodiment of the present invention.

Referring to FIG. 2, the semiconductor device includes a memory block 100, a voltage generator 200, a block decoder 300, and a pass selector 400.

The memory block 100 includes a plurality of memory cells MN<n:0>. A plurality of local word lines LWL<n:0> is coupled to the gates of the memory cells MN<n:0>.

The voltage generator 200 supplies operating voltages, such as a program voltage, a read voltage, and a pass voltage, to global word lines GWL<n:0> in the program and read operations of the semiconductor device.

The block decoder 300 generates a block select signal BLKWL of a high voltage level when the memory block 100 is a selected memory block and generates the block select signal BLKWL of a ground voltage level when the memory block 100 is an unselected memory block.

The pass selector 400 electrically connects the global word lines GWL<n:0> to the local word lines LWL<n:0> in response to the block select signal BLKWL of the block decoder 300 so that the operating voltages generated from the voltage generator 200 are transferred to the gates of the memory cells MN<n:0>. The pass selector 400 includes a plurality of high voltage transistors.

FIG. 3 is a cross-sectional view of the semiconductor device for illustrating the high voltage transistor and the metal wires arranged over the high voltage transistor shown in FIG. 2. In an embodiment of the present invention, only one of the high voltage transistors is shown and described as an example.

Referring to FIG. 3, the high voltage transistor 504 of the pass selector 400 includes a gate insulation layer 501, a gate conductive layer 502, and a metal electrode layer 503 all of which are sequentially stacked over a semiconductor substrate 500. Junctions 505 and 506 are formed in regions of the semiconductor substrate 500 neighboring the high voltage transistor 504. One of the junctions 505 and 506 is coupled to the local word lines LWL, and the other thereof is coupled to the global word lines GWL.

A plurality of metal wires M1 to M9 is formed on the interlayer dielectric layer 507 formed on the entire structure including the high voltage transistor 504. Here, the metal wires M1 to M9 are the local word lines LWL coupled to the memory cells MN of the memory block 100, and may be coupled to the junction of an adjacent high voltage transistor.

The metal wires M1 to M9 are arranged within a width of a gate for the high voltage transistor 504. In other words, the metal wires M1 and M9 arranged at outer edges, among the plurality of metal wires M1 to M9, are arranged within the gate width of the high voltage transistor 504 so that they are not arranged over the junctions 505 and 506. This may be achieved by reducing the widths of the metal wires M1 to M9. That is, a total width of the metal wires M1 to M9 is controlled so that the total width is smaller than the gate width of the high voltage transistor 504.

Since the metal wires M1 to M9 are not arranged over the junctions 505 and 506, the junction coupled to the global word lines is not coupled to the metal wires M1 or M9 although a high voltage is applied to the junction at the time of a program operation. Accordingly, a voltage drop of an operating voltage supplied to the global word lines can be reduced.

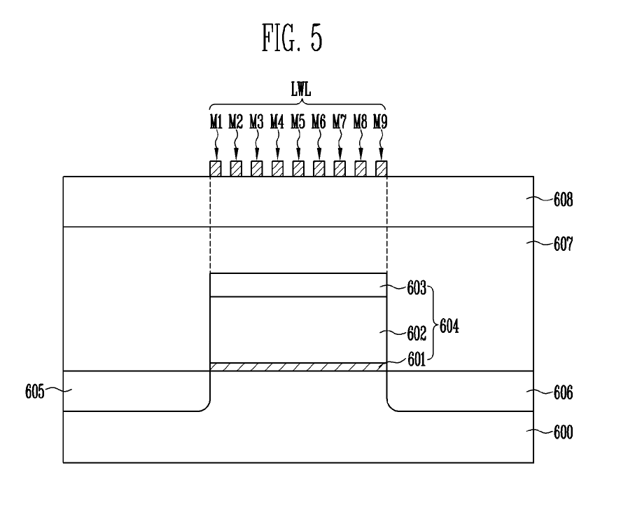

FIG. 4 is a plan view of the high voltage transistor 504 and the metal wires LWL shown in FIG. 3.

Referring to FIG. 4, the metal wires M1 to M9 are arranged to pass over the gate of the high voltage transistor 504, but are not arranged over the junctions 505 and 506 which are formed in regions neighboring the gate of the high voltage transistor 504.

FIG. 5 is a cross-sectional view of a semiconductor device for illustrating a high voltage transistor and metal wires arranged over the high voltage transistor according to an embodiment of the present invention.

Referring to FIG. 5, the high voltage transistor 604 of the pass selector includes a gate insulation layer 601, a gate conductive layer 602, and a metal electrode layer 603 which are sequentially stacked over a semiconductor substrate 600.

Junctions 605 and 606 are formed in regions of the semiconductor substrate 600 neighboring the high voltage transistor 604. One of the junctions 605 and 606 is coupled to the local word lines LWL, and the other thereof is coupled to the global word lines GWL.

A first interlayer dielectric layer 607 and a second interlayer dielectric layer 608 are formed on the entire structure including the high voltage transistor 604. A plurality of metal wires M1 to M9 is formed on the second interlayer dielectric layer 608. The plurality of metal wires M1 to M9 are the local word lines LWL coupled to the memory cells MN of the memory block 100. The plurality of metal wires M1 to M9 are the local word lines coupled to the junction of an adjacent high voltage transistor. If the metal wires M1 to M9 are formed on the second interlayer dielectric layer 608 as described above, a distance from the junctions 605 and 606 is increased and thus a coupling phenomenon can be reduced, as compared with the metal wires M1 to M9 formed on the first interlayer dielectric layer 607.

The metal wires M1 to M9 are formed within the gate width of the high voltage transistor 604. The metal wires M1 and M9 arranged at outer edges, among the plurality of metal wires M1 to M9, are arranged within the gate width of the high voltage transistor 604 so that they are not arranged over the junctions 605 and 506. This may be achieved by reducing the width of the metal wires M1 to M9. That is, a total width of the metal wires M1 to M9 is controlled so that the total width is smaller than the gate width of the high voltage transistor 604.

Since the metal wires M1 to M9 are not arranged over the junctions 605 and 606, the junction coupled to the global word lines may not be coupled to the metal wires M1 or M9 although a high voltage is supplied to the junction during a program operation. Accordingly, a voltage drop of an operating voltage supplied to the global word lines can be reduced.

As described above, according to this disclosure, the metal wires over the high voltage transistor are formed only within the gate width of the high voltage transistor by reducing a total width of the metal wires so that the metal wires are not arranged over the junctions. Accordingly, the sheet resistance of the junction can be controlled and thus a drop in the voltages of the global word lines can be reduced.

What is claimed is:

1. A semiconductor device, comprising:
a plurality of gates of high voltage transistors configured to couple a plurality of global word lines to a plurality of local word lines; and
the plurality of local word lines arranged over each of the gates,
wherein the plurality of local word lines is arranged within a width of the gate.

2. The semiconductor device of claim 1, wherein a total width of the plurality of local word lines arranged over the gate is smaller than the width of each gate.

3. The semiconductor device of claim 1, wherein the plurality of local word lines arranged over the gate is formed over one or more of interlayer dielectric layers formed on the high voltage transistor.

4. The semiconductor device of claim 1, further comprising junctions formed in regions of a semiconductor substrate, neighboring the high voltage transistors, and coupled to the plurality of global word lines, wherein the plurality of local word lines is not arranged over the junctions.

5. A semiconductor device, comprising:
a memory block comprising a plurality of memory cells having gates coupled to a plurality of local word lines;
a voltage generator configured to supply operating voltages to a plurality of global word lines; and
a pass selector configured to include a plurality of high voltage transistors for coupling the plurality of local word lines to the plurality of global word lines,
wherein the plurality of local word lines is arranged over each of the high voltage transistors and arranged within a width of a gate for the high voltage transistor.

6. The semiconductor device of claim 5, wherein a total width of the plurality of local word lines arranged over the gate is smaller than the width of each gate.

7. The semiconductor device of claim 5, wherein the plurality of local word lines arranged over the gate is arranged over one or more of interlayer dielectric layers formed on the high voltage transistor.

8. The semiconductor device of claim 5, further comprising junctions formed in regions of a semiconductor substrate, neighboring the high voltage transistors, and coupled to the plurality of global word lines, wherein the plurality of local word lines is not arranged over the junctions.

9. A semiconductor device, comprising:
high voltage transistors formed on a semiconductor substrate;
source and drain regions formed within the semiconductor substrate on both sides of each of the high voltage transistors; and
wires arranged over a gate for the high voltage transistor so as not to overlap with the source and drain regions.

10. The semiconductor device of claim 9, wherein a total width of the wires arranged over the gate is smaller than a width of the gate.
